(19) United States
(12) Patent Application Publication
(10) Pub. No.: US 2025/0210520 A1
(43) Pub. Date: Jun. 26, 2025

(54) DUAL GATE CUT WITH BACKSIDE POWER DELIVERY

(71) Applicant: International Business Machines Corporation, Armonk, NY (US)

(72) Inventors: Lijuan Zou, Albany, NY (US); Tao Li, Slingerlands, NY (US); Ruilong Xie, Niskayuna, NY (US); Nicolas Jean Loubet, GUILDERLAND, NY (US)

(21) Appl. No.: 18/391,991

(22) Filed: Dec. 21, 2023

(51) Int. Cl. H01L 23/528; H01L 29/06; H01L 29/40; H01L 29/417; H01L 29/423; H01L 29/66; H01L 29/775

(52) U.S. Cl. CPC H01L 23/5286; H10D 30/014; H10D 30/43; H10D 30/6729; H10D 30/6735; H10D 62/121; H10D 64/01

(57) ABSTRACT

A semiconductor device includes a row of source/drain regions delineating a frontside and a backside opposite the frontside of the semiconductor device. A front gate cut from the frontside of the device has a depth that is less than a height of a gate structure for the semiconductor device. A back gate cut from the backside of the semiconductor device contacts the front gate cut.

### BACKGROUND

The present disclosure relates to semiconductor devices, and more particularly to semiconductor devices including a two-sided gate cut that enables cell height scaling.

Modern integrated circuits are made up of active devices including transistors. Field effect transistors (FETs) are widely used in the electronics industry for switching, amplification, filtering and other tasks related to both analog and digital electrical signals. Most common among these are metal oxide semiconductor field effect transistors (MOSFET or MOS), in which a gate structure is energized to create an electric field in an underlying channel region of a semiconductor body, by which electrons are allowed to travel through the channel between a source region and a drain region of the semiconductor body.

Nanosheet devices are a form of a FET device that provides for increased device integration and improved scaling. However, with increased scaling certain difficulties have arisen. For example, when scaling a cell height, epitaxial semiconductor material can merge due to the reduction in size. This can limit successful scaling.

Gate cut structures formed in anisotropically etched trenches can also limit scaling of the cell height. For example, as the depth of a gate cut is increased, the upper width for the gate cut also increases. This is a function of the etch process employed in forming the trenches in fabricating the gate cut. In some instances, for deeper gate cut structures, the upper width of the gate cut can consume a significant amount of the gate electrode that the gate cut is dividing. This can reduce the surface area for contact surfaces for contacting the gate structure. As the cell height is scaled to lower dimensions, the width of the gate cut consumes a greater and greater amount of the gate electrode.

Therefore, a need exists for a gate cut that reduces impact to cell height and can enable further scaling in semiconductor devices. A further need exists for preventing merging of source/drain regions due to such scaling.

### SUMMARY

In accordance with embodiments of the present invention, semiconductor devices are provided that overcome the aforementioned disadvantages in cell height scaling and epitaxial growth control for the source/drain region. To facilitate cell height scaling of semiconductor devices having gate cut structures, the methods and structure described employ a front gate cut having a shallow depth. By employing a shallow depth gate cut, the width of the upper surface of the gate cut can be minimized. In combination with the front gate cut, a back gate cut is employed that extends from a backside surface of the structure into contact with the front gate cut to section the gate structure.

In an embodiment, a semiconductor device is provided that includes a row of source/drain regions delineating a frontside and a backside opposite the frontside of the semiconductor device. The semiconductor device further includes a front gate cut from a frontside of the device, wherein the front gate cut has a depth that is less than a height of a gate structure for the semiconductor device. The semiconductor device can also include a back gate cut from a backside of the semiconductor device. The back gate cut contacts the front gate cut to isolate gate structures adjacent to the gate cut. In some embodiments, the back gate cut extends through an isolation region. In some embodiments, the back gate cut has a height that is less than the height of the gate structure.

In some examples, the front gate cut together with the back gate cut section the gate structure into first gate structure for a first field effect transistor and a second gate structure for a second field effect transistor. The first and second field effect transistors may be nanosheet devices. In some embodiments, the source regions of the row of source/drain regions are separated from drain regions of the source/drain regions by backside source/drain cut structures.

In some embodiments, at least one source/drain region is electrically contacted by a backside contact to a power distribution network.

In another embodiment, a semiconductor device is provided that includes a row of source/drain regions delineating a frontside and a backside opposite the frontside of the semiconductor device. The semiconductor device can also include a front gate cut from a frontside of the device, wherein the front gate cut has a depth that is less than a height of a gate structure for the semiconductor device. The semiconductor device can also include a back gate cut from a backside of the semiconductor device which contacts the front gate cut. The semiconductor device may also include backside source/drain cut structures. In some embodiments, the backside source/drain cut structures obstruct merging between source/drain regions of the row of source/drain regions. In some embodiments, the front gate cut together with the second gate cut section the gate structure into first gate structure for a first field effect transistor and a second gate structure for a second field effect transistor. In some embodiments, the second back gate cut extends through an isolation region.

In some embodiments, at least one of the first field effect transistor and the second field effect transistor is a nanosheet device. At least one of row of source/drain regions is electrically contacted by a backside contact to a power distribution network. The back gate cut has a height that is less than the height of the gate structure.

In another embodiment, a semiconductor device is provided that includes a gate structure in contact with the first stack of nanosheets and the second stack of nanosheets. The semiconductor device includes a front gate cut having a depth that is less than a height of the gate structure. The semiconductor device can further include a back gate cut extending into contact with the front gate cut, wherein the front gate cut in combination with the back gate cut together divides the gate structure into a first gate structure and a second gate structure. In some embodiments, the back gate cut has a height that is less than the height of the gate structure. In some embodiments, the back gate cut structure extends through an isolation region. The semiconductor device can include at least one source/drain region electrically contacted by a backside contact to a power distribution network.

In another embodiment, a semiconductor device is provided that includes a first stack of nanosheets, a second stack of nanosheets and a third stack of nanosheets, and a gate structure in contact with the first stack of nanosheets, the second stack of nanosheets and the third stack of nanosheets. In some embodiments, a first gate cut structure is present in the gate structure having a depth that is less than a height of the gate structure. A second gate cut structure extends into contact with the first gate cut structure. The first gate cut structure and the second gate cut structure (in combination) divide the gate structure into a first gate structure and a second gate structure. The first gate structure is for a first field effect transistor having channel regions in the first stack of nanosheets. The second gate structure is shared between a second field effect transistor having channel regions in the second stack of nanosheets and a third field effect transistor having channel regions in the third stack of nanosheets.

In an embodiment, the third field effect transistor is separated from the second field effect transistor by another isolation region that includes a partial back side gate cut that partially extends into the second gate structure.

In some embodiments, the first field effect transistor includes a first source region and a first drain region, wherein a first of the first source region and first drain region is electrically contacted by a front side contact that is in electrical communication with back end of line wiring, and a second of the first source region and the first drain region is electrically contacted by a back side contact that is in electrical communication with a buried power rail. The buried power rail is in electrical communication with a back side power distribution network.

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1 is a top down view of a semiconductor device having a dual side gate cut and backside source/drain cut for direct backside contact and backside power distribution network, in which the top down view illustrates the relationship between cross-section lines identified by X-X, Y1-Y1 and Y2-Y2 for each of the side-cross sectional figures provided herein, in accordance with an embodiment of the present invention;

FIG. 2 is a side cross-sectional view along section line X-X of FIG. 1 showing a completed structure having a backside source/drain contact, in accordance with an embodiment of the present invention;

FIG. 3 is a side cross-sectional view along section line Y1-Y1 of FIG. 1, showing backside source/drain cut structures, in accordance with an embodiment of the present invention;

FIG. 4 is a side cross-sectional view along second line Y2-Y2 of FIG. 1 showing a gate cut structure including a front gate cut in combination with a back gate cut to section that gate structure, in accordance with an embodiment of the present invention;

FIG. 5 is a side cross-sectional view along section line X-X of an initial semiconductor device structure following front end of the line processing, middle of the line processing, back end of the line processing, and wafer bonding, in accordance with an embodiment of the present invention;

FIG. 6 is a side cross-sectional view along section line Y1-Y1 of the structure depicted in FIG. 5 depicting source/drain regions, in accordance with one embodiment of the present invention;

FIG. 7 is a side cross-sectional view along section line Y2-Y2 of the structure depicted in FIG. 5 showing a front gate cut, in accordance with one embodiment of the present invention;

FIG. 8 is a side cross-sectional view along section line X-X depicting removing a substrate, removing an etch stop layer and forming a cap dielectric to the structure depicted in FIG. 5, in accordance with one embodiment of the present invention;

FIG. 9 is a side cross-sectional view along section line Y1-Y1 of the structure depicted in FIG. 8 depicting removing a substrate, removing an etch stop layer and forming a cap dielectric to the structure depicted, in accordance with one embodiment of the present invention;

FIG. 10 is a side cross-sectional view along section line Y2-Y2 of the structure depicted in FIG. 8 depicting removing a substrate, removing an etch stop layer and forming a cap dielectric to the structure depicted, in accordance with one embodiment of the present invention;

FIG. 11 is a side cross-sectional view along section line X-X depicting forming a backside gate cut, and forming a backside source/drain cut structure, in accordance with one embodiment of the present invention;

FIG. 12 is a side cross-sectional view along section line Y1-Y1 of the structure depicted in FIG. 11 depicting a backside source/drain cut structure, in accordance with one embodiment of the present invention;

FIG. 13 is a side cross-sectional view along section line Y2-Y2 of the structure depicted in FIG. 11 showing a backside gate cut, in accordance with one embodiment of the present invention;

FIG. 14 is a side cross sectional view along section line X-X depicting forming openings for the backside contacts to source/drain regions, in accordance with one embodiment of the present invention;

FIG. 15 is a side cross-sectional view along section line Y1-Y1 of the structure depicted in FIG. 14 illustrating forming openings for the backside contacts to source/drain regions, in accordance with one embodiment of the present invention;

FIG. 16 is a side cross-sectional view along section line Y2-Y2 of the structure depicted in FIG. 14 illustrating openings for the backside contacts to source/drain regions, in accordance with one embodiment of the present invention;

FIG. 17 is a side cross sectional view along section line X-X depicting openings filled with conductive material for the backside contacts to source/drain regions, in accordance with one embodiment of the present invention;

FIG. 18 is a side cross-sectional view along section line Y1-Y1 of the structure depicted in FIG. 14 showing openings filled with conductive material for the backside contacts to source/drain regions, in accordance with one embodiment of the present invention; and

FIG. 19 is a side cross-sectional view along section line Y2-Y2 of the structure depicted in FIG. 14 showing openings filled with conductive material for the backside contacts to source/drain regions, in accordance with one embodiment of the present invention.

### DETAILED DESCRIPTION

Detailed embodiments of the claimed methods and structures are described herein; however, it is to be understood that the described embodiments are merely illustrative of the claimed structures and methods that may be embodied in various forms. In addition, each of the examples given in connection with the various embodiments are intended to be illustrative, and not restrictive. Further, the figures are not necessarily to scale, some features may be exaggerated to show details of particular components. Therefore, specific structural and functional details described herein are not to be interpreted as limiting, but merely as a representative basis for teaching one skilled in the art to variously employ the methods and structures in accordance with embodiments of the present invention.

In an embodiment, structures and methods can provide a dual side gate cut and a backside source/drain cut structure for direct backside contacts to a backside power distribution network in stacked devices. It has been determined that when cell height is scaling, merging of epitaxially grown material is a concern. Additionally, gate cut structures formed using anisotropically etched trenches can also limit scaling of the cell height. Scaling refers to reducing critical dimensions of components on a semiconductor device to increase device density. In some instances, for deeper gate cut trenches, the upper width of the gate cut can consume a significant amount of the gate electrode that the gate cut is dividing. This can reduce the surface area for contact surfaces for contacting the gate structure. As the cell height is scaled to lower dimensions, the width of the gate cut structure consumes a greater and greater amount of the gate electrode.

In some embodiments, the methods and structures described herein use a shallow front gate cut in combination with a backside gate cut to minimize the width of the gate cut on the front of the device. In some embodiments, the depth of the front gate cut is less than the height of the gate structure. To complete the sectioning or division of the gate structure, a back gate cut is formed that contacts the front gate cut. By minimizing the depth of the front gate cut, the width of the top of the front gate cut is also reduced. For example, the width of the top of the front gate cut can be reduced by at least half when compared to a single gate cut that extends from the front of the device through the entirety of the gate structure. For example, the methods and structures described herein can reduce the width of the top of the front gate cut by at least half when compared to a single gate cut that extends from the front of the device through the entirety of the gate structure. Additionally, backside source/drain cut structures are employed that obstruct merging of the source/drain regions of adjacent devices. These features help to minimize difficulties that can occur during scaling of device processing, such as scaling of the gate height of a semiconductor device structure including stacked nanosheets and gate all around gate structures.

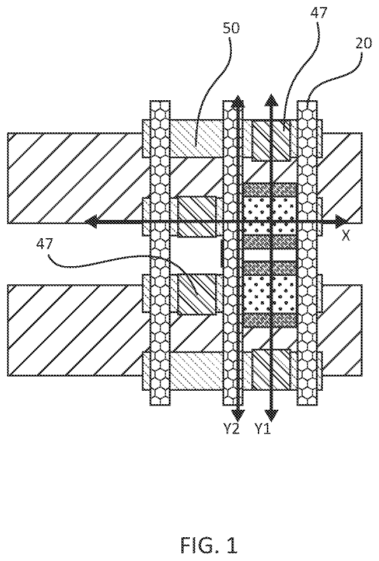

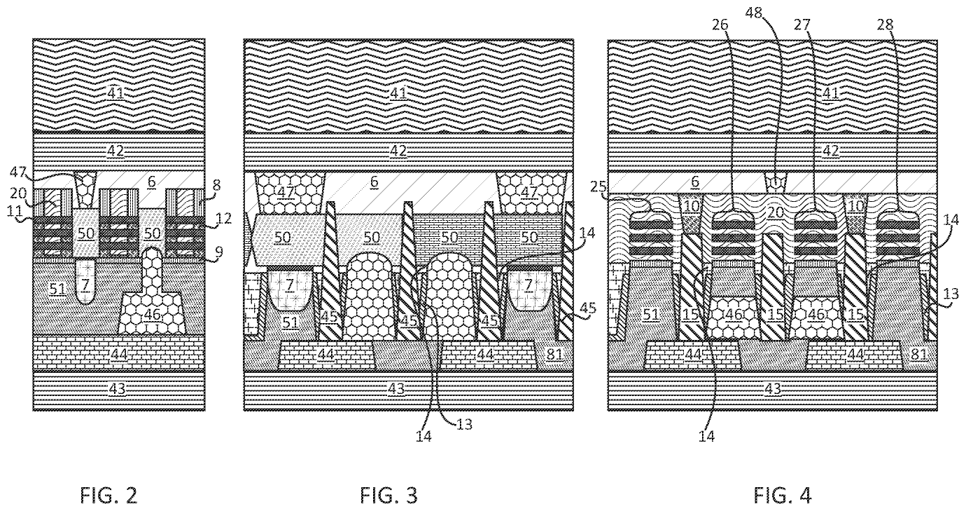

The methods and structures in accordance with embodiments of the present invention are now described with reference to FIGS. 1-19.

Referring to FIGS. 1-4, an embodiment of a semiconductor device is shown employing a dual side gate cut and backside source/drain cut including a direct backside contact (BC) to a backside power distribution network (BSPDN). The semiconductor device can include field effect transistors. A field effect transistor has three terminals, e.g., gate, source and drain. The channel regions of the semiconductor device are provided by nanosheets 11.

A front gate cut 10 is depicted in FIG. 4 having a shallow depth. The term “shallow” refers to a front gate cut that has a depth measured from the top of the gate structure 20 that is less than the height of the gate structure 20. It is noted that the structures described herein may include shallow gate cuts for the front gate cut 10, as well as the back gate cut 15, as either of these gate cuts have a height that is less than the gate structure 20. A “gate structure” means a structure used to control output current (e.g., flow of carriers in the channel) of a semiconducting device, such as a field effect transistor (FET). In the embodiments depicted in FIGS. 1-4, the gate structure 20 can include a high-k gate dielectric, and a metal gate conductor, which may be referred to as a high-k metal gate (HKMG). The channel regions in the embodiments depicted in FIGS. 1-4 may be nanosheets 11 of semiconductor material.

The structure depicted in FIGS. 1-4 includes a back gate cut 15 that is self-aligned and merges with a front gate cut 10. The back gate cut 15 and the front gate cut 10 may both be composed of a dielectric material fill. In some embodiments, the dielectric fill within the back gate cut 15 and the front gate cut 10 provides that the gate structure 20 is sectioned or divided to provide three separate gate structures, as illustrated in FIG. 3.

Still referring to FIGS. 1-4, each semiconductor device includes a stack of nanosheets 11, wherein a gate structure 20 is present on a channel region portion for the stack of nanosheets 11. As used herein, the term “channel” is the region underlying the gate structure and between the source and drain of a semiconductor device that becomes conductive when the semiconductor device is turned on. As used herein, the term “drain” means a doped region in semiconductor device located at the end of the channel, in which carriers are flowing out of the transistor through the drain. As used herein, the term “source” is a doped region in the semiconductor device, in which majority carriers are flowing into the channel. Source and drain regions can be referred to collectively as source/drain regions or S/D regions.

A “nanosheet” is a two-dimensional nanostructure with thickness in a scale ranging from 1 nm to 100 nm. In one example, the nanosheets 11 may be composed of a type IV semiconductor, such as silicon (Si), germanium (Ge) and/or silicon germanium (SiGe). The nanosheets 11 may also be provided by a type III-V semiconductor material, such as gallium arsenide (GaAs).

The term “gate all around (GAA)” denotes a gate structure 20 that encloses the channel region from both a frontside and backside of the channel. In some embodiments, a conformal dielectric layer is formed on suspended channels of a multiple channel region device, such as a vertically stacked nanosheet or nanowire structure. Thereafter, a gate conductor is formed, in which a single gate structure may enclose a plurality of channel regions having a conformal gate dielectric present thereon. In some instances, the gate all around (GAA) structure may include a conformal gate dielectric layer (not shown) composed of a high-k gate dielectric material, and a gate conductor of an elemental metal (which may be referred to as a metal gate).

FIGS. 1-4 depict four field effect transistors that are identified by their respective stacks of nanosheets 11 that provide the channel regions for the field effect transistors. For example, a first field effect transistor may employ a first stack 25 of nanosheets 11 for the channel of the device. For example, a second field effect transistor may employ a second stack 26 of nanosheets 11 as the channel region for the device. For example, a third field effect transistor may employ a third stack 27 of nanosheets 11 as the channel region for the device. For example, a fourth field effect transistor may employ a fourth stack 28 of nanosheets 11 as the channel region for the device.

Two field effect transistors having a shared gate structure portion include the nanosheets channel stacks 26, 27 that are contacted by the portion of the gate structure 20 that does not include a front gate cut 10. In some embodiments, the two field effect transistors with the shared gate structure portion can also include a back gate cut 15 that only partially separates the gate structure 20 of the two field effect transistors having the shared gate structure.

The field effect transistors may also include source/drain regions 50. In some embodiments, the source/drain regions 50 are formed onto the edges of the nanosheets 11 that provide the channel regions. In some embodiments, the source/drain regions 50 include an epitaxial semiconductor material. The term “epitaxial material” denotes a material that is formed using epitaxial growth. The terms “epitaxial growth and/or deposition” means the growth of a semiconductor material on a deposition surface of a semiconductor material, in which the semiconductor material being grown has substantially the same crystalline characteristics as the semiconductor material of the deposition surface. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation.

At least one of the source/drain regions 50 may be connected to the power rail 44 by a backside contact 46. The power rail 44 is in electrical communication with a backside power distribution network 43. In some embodiments, at least one of the source/drain regions 50 may have a front side contact 47 on an opposing side of the backside contact 46. The frontside contact 47 may provide electrical communication from an upper surface from at least one of the source/drain regions 50 to an electrical communication network that is present in a back end of the line level 42.

Referring to FIG. 3, the structures described herein also include backside source/drain cut structures 45 to separate the epitaxial material for the source/drain regions 50. The backside source/drain cut structures 45 can avoid merging of the epitaxial source/drain material that provides the source/drain regions 50. The backside source/drain cut structures 45 can be self-aligned with source/drain regions 50.

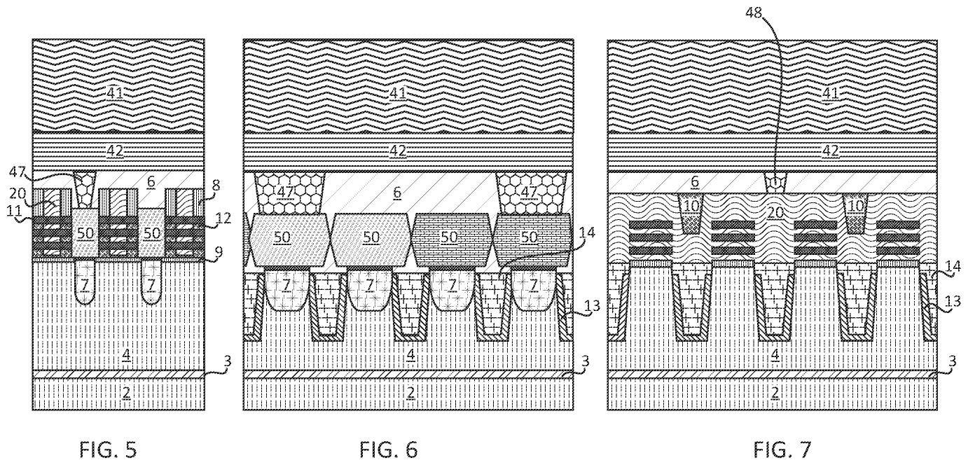

The structures, illustrated in FIGS. 1-4, are now described in greater detail in accordance with the following embodiments of a method for forming a semiconductor device. It is noted that the following methods are only some examples of methods for forming the structures depicted in FIGS. 5-19.

FIGS. 5-7 illustrate an embodiment of an initial structure that can provide a starting point for a method for forming a semiconductor device that includes dual side gate cut and backside source/drain cut structures for direct backside contact to backside power distribution networks. The initial structure can be produced by a process sequence that can include front end of the line processing including forming a front gate cut 10, middle of the line processing, and back end of the line processing, and carrier wafer bonding.

The structures depicted in FIGS. 5-7 include stacks of nanosheets 11, a shallow trench isolation region (including a shallow trench isolation liner 13 and a shallow trench isolation fill 14) on an upper semiconductor layer 4, an etch stop layer 3 and a substrate 2. The upper semiconductor layer 4, etch stop layer 3 and substrate 2 may each be composed of semiconductor materials.

The stack of nanosheets 11 may also be provided by a type IV semiconductor material, such as silicon, silicon germanium, etc., or a type III-V semiconductor material, such as gallium arsenide (GaAs). It is noted that any semiconductor material that may serve as the channel region of a field effect transistor may be employed for the nanosheets 11. It is noted that the stack of nanosheets may include a first sacrificial nanosheet that is present on the upper semiconductor layer 4. Nanosheets 11 that ultimately provide the channel regions of the semiconductor devices are also present in the stack. A second sacrificial nanosheet is present in the stack between the nanosheets, which provide the channel regions for the field effect transistors. The second sacrificial nanosheet provides spacing for suspension of the nanosheets 11, which provide the channel regions in a gate all around configuration. The details of these process sequences are omitted for brevity, but they are part of front end of the line processing.

For example, a stack of semiconductor material layers is provided including layers that ultimately provide nanosheets 11 for the channel regions that are separated by sacrificial layers. The stack of semiconductor material layers can be produced using deposition processes, such as chemical vapor deposition or atomic layer deposition, in which the geometry of the stack can be defined using photolithography and subtractive etching, such as reactive ion etching.

It is noted that in some embodiments, after etching the stack that provides the material layers for the nanosheets 11, the etch process may be continued into the upper semiconductor layer 4 to provide the trenches for the shallow trench isolation regions. The shallow trench isolation regions include a shallow trench isolation liner 13 and a shallow trench isolation fill 14. Because the shallow trench isolation regions are formed in trenches that are aligned to the edges of the stacks of material layers for the nanosheets 11, the shallow trench isolation regions are aligned to the edges of the channel regions. This also means the shallow trench isolation regions are aligned with the source/drain regions 50 that are present at the ends of the channel regions provided by the nanosheets 11.

In combination with the process steps of a replacement gate process, the sacrificial layers of the material stack are removed during processing of the material sheets that are processed to provide nanosheet geometries for the channel regions of the field effect transistors. The thickness of the nanosheets 11 that provide the channel regions of the field effect transistors may range from 1 nm to 30 nm, and in some examples may range from 5 nm to 20 nm. In some embodiments, a spacer may be used to support the nanosheets during processing following removal of the sacrificial layers in the stack. That spacer may be referred to as an inner spacer 12, and may be composed of a dielectric material, such as an oxide, e.g., silicon oxide (SiO₂) or nitride, e.g., silicon nitride. Additionally, a self-aligned substrate isolation layer 9 may be formed between the lowest nanosheet that provides a channel region and the substrate. This spacer electrically isolates the lowest channel from the underlying structure the lowest channel is present on. The self-aligned substrate isolation layer 9 may be composed of a dielectric material, such as silicon oxide, silicon nitride and/or silicon oxynitride. Further, a gate sidewall spacer 8 may be formed adjacent to sidewalls of the gate structure 20. In some embodiments, the gate sidewall spacer 8 may have a same composition as the self-aligned substrate isolation layer 9.

The replacement gate process for providing the gate structure 20 employs sacrificial materials. By “replacement”, e.g., as used to describe the replacement gate structure, it is meant that the structure is present during processing of the semiconductor device, but is removed from the semiconductor device prior to the device being completed. As used herein, the term “replacement gate structure” denotes a sacrificial structure that dictates the geometry and location of the later formed functioning gate structure. The “functional gate structure” operates to switch the semiconductor device from an “on” to “off” state, and vice versa. The gate structure 20 is a functional gate structure.

FIGS. 5-7 also illustrate forming a backside contact placeholder 7. The backside contact placeholder 7 can be considered a deep placeholder that can be substituted with a backside contact after forming the source/drain regions 50, and following backside processing that removes the substrate 2, etch stop layer 3 and upper semiconductor layer 4. The backside contact placeholder 7 is formed by etching a trench in the upper semiconductor layer 4 using an anisotropic etch, such as reactive ion etching (RIE), followed by filling the trench with a dielectric material, e.g., an oxide, nitride or oxynitride material, which in some implementations can include carbon. The composition is generally selected for etch selectivity in removal of the backside contact placeholder 7 in the process sequence that forms the backside contact 46.

FIGS. 5-7 illustrate epitaxial growth of the semiconductor material for the source/drain regions 50. The source/drain regions 50 may be formed by an epitaxial deposition method. The source/drain regions 50 may be composed of epitaxial semiconductor material that is doped to an n-type or p-type dopant. In some embodiments, the epitaxial semiconductor material that provides the source/drain regions 50 may be composed of silicon (Si), germanium (Ge), silicon germanium (SiGe), silicon doped with carbon (Si:C), or the epitaxial semiconductor material that provides the source and drain regions may be composed of a type III-V compound semiconductor, such as gallium arsenide (GaAs).

The epitaxial semiconductor material for the source/drain regions 50 may be in situ doped to a p-type or n-type conductivity. The term “in situ” denotes that a dopant, e.g., n-type or p-type dopant, is introduced to the base semiconductor material, e.g., silicon or silicon germanium, during the formation of the base material. For example, an in situ doped epitaxial semiconductor material may introduce n-type or p-type dopants to the material being formed during the epitaxial deposition process that includes n-type or p-type source gases. In the embodiments in which the semiconductor device being formed has p-type source and drain regions, and is referred to as a p-type semiconductor device, the doped epitaxial semiconductor material is doped with a p-type dopant to have a p-type conductivity. As used herein, “p-type” refers to the addition of impurities to an intrinsic semiconductor that creates deficiencies of valence electrons. In a type IV semiconductor, such as silicon, examples of p-type dopants, i.e., impurities, include but are not limited to, boron, aluminum, gallium and indium. As used herein, “n-type” refers to the addition of impurities that contributes free electrons to an intrinsic semiconductor. In a type IV semiconductor, such as silicon, examples of n-type dopants, i.e., impurities, include but are not limited to antimony, arsenic and phosphorous.

As illustrated in FIGS. 5-7, the epitaxial semiconductor material for the source/drain regions 50 can be grown until the source/drain regions 50 for the different field effect transistors touch, e.g., the epitaxial semiconductor material merges. Any potential for shorting between these features in a final device structure is removed by later formed backside source/drain cut structures 45.

Following the growth of the epitaxial semiconductor material for the source/drain regions 50, an upper interlevel dielectric layer 6 is deposited and planarized. The upper interlevel dielectric layer 6 may have a composition selected from the group consisting of silicon-containing materials such as SiO₂, Si₃N₄, SiOₓN_{y}, SiC, SiCO, SiCOH, and SiCH compounds; the above-mentioned silicon-containing materials with some or all of the Si replaced by Ge; carbon-doped oxides; inorganic oxides; inorganic polymers; hybrid polymers; organic polymers such as polyamides or SiLK™; other carbon-containing materials; organo-inorganic materials such as spin-on glasses and silsesquioxane-based materials; and diamond-like carbon (DLC, also known as amorphous hydrogenated carbon, α-C:H). The interlevel dielectric layer may be deposited using a deposition process, such as spin on deposition (SOD) followed by a planarization process, such as chemical mechanical planarization (CMP).

Still referring to FIGS. 5-7, the front end of the line portion of the method can further include continue removing the replacement gate structure and forming a functional gate structure (gate structure 20), which may include a high-k gate dielectric and a metal gate conductor, which can be collectively referred to as high-k metal gate. The replacement gate structure can be removed using a selective etch process without removing the semiconductor material layers in the stack for providing the nanosheets 11.

As noted above, the replacement gate process may include steps used for configuring the nanosheets 11 that provide the channel regions of the field effect transistors. In some embodiments, once the sacrificial gate structure is removed, the sacrificial semiconductor layers are removed by a selective etch, leaving semiconductor layers that provide the nanosheet channel regions. Suspension of the nanosheets 11 may be supported by the inner spacers 12. In some embodiments, the suspended semiconductor layers provided by the nanosheets 11 may be further processed to provide reduced dimensions. In some embodiments, the suspended structure, e.g., semiconductor material layer provided by nanosheets 11, may be further processed to a geometry in the nanometer regime. For example, the nanosheets 11 may be thinned by a process that includes controlling thinning of the silicon, which can include ozone (O₃) oxidation, SC1 chemistry oxidation and/or dry oxidation.

The replacement gate method can form a functional gate structure in the space that was created by removing the replacement gate structure. In some embodiments, the gate structure 20 includes a high-k gate dielectric and a metal gate conductor. The gate dielectric may be a high-k dielectric material, such as hafnium oxide (HfO₂). The gate dielectric for the gate all around structure may be deposited using chemical vapor deposition (CVD) or atomic layer deposition (ALD) and is present on the entirety of the exterior surfaces of the suspended nanosheets 11. The metal gate conductor for the gate structure 20 may encapsulate the suspended nanosheets 11 including the gate dielectric present on the exterior surfaces of the suspended nanosheets 11. The gate conductor may be composed of a metal, such as tungsten (W) or an n-type or p-type work function metal, e.g., titanium nitride. It is noted that the prior examples are provided for illustrative purposes only, and are not intended to limit the teachings of this disclosure solely thereto. For example, the gate conductor for the gate all around structure that provides the gate structure 20, e.g., gate all around gate structure, may be composed of other conductive materials, such as a doped semiconductor, e.g., n-type doped polysilicon. Each of the aforementioned layers may be formed using a deposition method, such as chemical vapor deposition, atomic layer deposition, plating, physical vapor deposition, etc.

In some embodiments, a conformal dielectric layer is formed on suspended channels of a multiple channel region device to provide a gate dielectric layer. Thereafter, a gate conductor is formed, in which a single gate structure may enclose a plurality of channel regions having the gate dielectric layer present thereon. In some instances, the gate all around structure may include a gate dielectric layer composed of a high-k gate dielectric material, and a gate conductor of an elemental metal, which may be referred to as a metal gate. A high-k gate dielectric layer may have a dielectric constant greater than silicon, and in some embodiments may be hafnium based, e.g., be composed of hafnium oxide.

Referring to again to FIGS. 5-7, in some embodiments, the materials deposited for the gate structure 20 may be further processed to form a front gate cut 10 having a shallow depth. The shallow depth of the front gate cut 10 means that the height of the front gate cut 10 is less that the height of the gate structure 20. The height of the gate structure refers to the height of the portion of the gate structure 20 that is not being cut when the front gate cut 10 is formed. For example, a height of the gate structure 20 may range from 20 nm to 100 nm. This can depend on how many nanosheets 11 are present for the channel regions of the field effect transistors. The front gate cut 10 is formed using photolithography that employs an etch mask to expose the portion of the gate structure 20, in which the front gate cut 10 is to be formed. An anisotropic etch, such as reactive ion etching (RIE), can form an opening for the front gate cut 10. The opening is then filled with a dielectric material, such as an oxide, e.g., silicon oxide, or nitride, e.g., silicon nitride, which is then planarized, e.g., by chemical mechanical planarization. The resultant structure is the front gate cut 10 depicted in FIG. 7.

The front gate cut 10 can be positioned centrally between two adjacent stacks of nanosheets 11. Therefore, the front gate cut 10 is positioned centrally with respect to the center of the shallow trench isolation regions, e.g., in the center of the shallow trench isolation liner 13 and shallow trench isolation fill 14. Because the front gate cut 10 is centrally positioned over the shallow trench isolation region, the later formed back gate cut 15 can be formed through the center of the shallow trench isolation region and be aligned with the front gate cut 10. Forming the front gate cut 10 at this stage of the process flow provides for at least two advantages: (1) each front gate cut 10 and back gate cut 15 can be etched to a shallow depth; and (2) the partial back gate cut 15 does not significantly etch away gate metals.

FIGS. 5-7 also depict one embodiment of forming middle of the line contacts, back end of the line contacts and bonding a carrier wafer 41 to the structure formed during front end of the line processing.

The middle of the line contacts may include the front side contacts 47 to the source/drain regions 50 and the gate contact 48 that are formed through the upper interlevel dielectric layer 6. In some embodiments, the middle of the line contacts include a frontside contact 47 to at least one of the source/drain regions 50. The frontside contact 47 extends metallization in the back end of the line level 42 to the source/drain regions 50. The middle of the line contacts can also include a gate contact 48 to the gate structure 20, which can also extend from metallization in the back end of the line level 42.

The back end of the line (BEOL) level 42 includes metal lines and vias that may be in electrical communication with the contacts produced in the middle of the line (MOL). The process sequence that is used for forming the metal lines and vias is a back end of the line (BEOL) process. In some embodiments, an interlevel dielectric layer is first deposited and then etched to form via openings to the underlying contacts. Thereafter, the via openings are then filled with an electrically conductive material, such as a metal, e.g., copper, to provide vias. Thereafter, a deposition, pattern and fill sequence is repeated to forms lines. This may be referred to as a single damascene method for forming lines and vias. However, dual damascene sequences are also applicable. The sequence of deposition, pattern and etch are repeated as many times as needed to form each level of metal lines and vias.

The carrier wafer 41 provides support to the structure, as the backside of the device is processed.

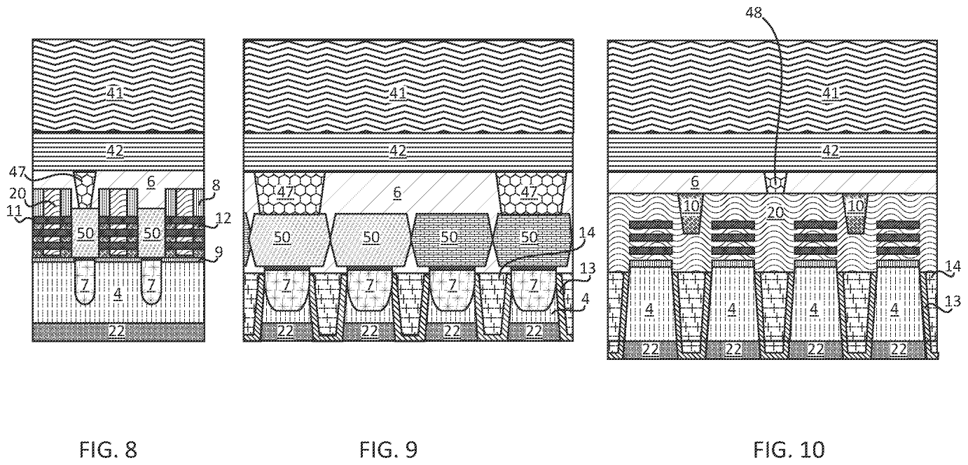

FIGS. 8-10 illustrate some embodiments of the resulting structure following a process sequence that includes flipping the structure depicted in FIGS. 5-7, and removing the substrate 2, the etch stop layer 3, as well as a portion of the upper semiconductor layer 4. These elements may be removed by selective etching. For example, the portions of the upper semiconductor layer 4 may then be removed by an etch process that is selective to the shallow trench isolation regions. In some embodiments, the etch process may be an anisotropic etch, such as reactive ion etching (RIE).

FIGS. 8-10 also illustrate forming a dielectric cap 22 in the recessed portions of the upper semiconductor layer 4 that was formed by etch processing following removing the etch stop layer 3. In one embodiment, the dielectric cap 22 may be formed by deposition of silicon carbide. It is noted that silicon carbide is only one composition that is suitable for the dielectric cap 22, and it is not intended that the present disclosure be limited to only this example. For example, other dielectric materials are equally applicable, so long at etch selectivity is maintained between the dielectric cap 22 and the shallow trench isolation liner 13. In some embodiments, the dielectric material that provides the dielectric cap 22 may be deposited using a deposition process, such as chemical vapor deposition, e.g., metal organic chemical vapor deposition and/or plasma enhanced chemical vapor deposition. Following deposition, the material layer that provides the dielectric cap 22 may be planarized until the shallow trench isolation liner 13 is exposed.

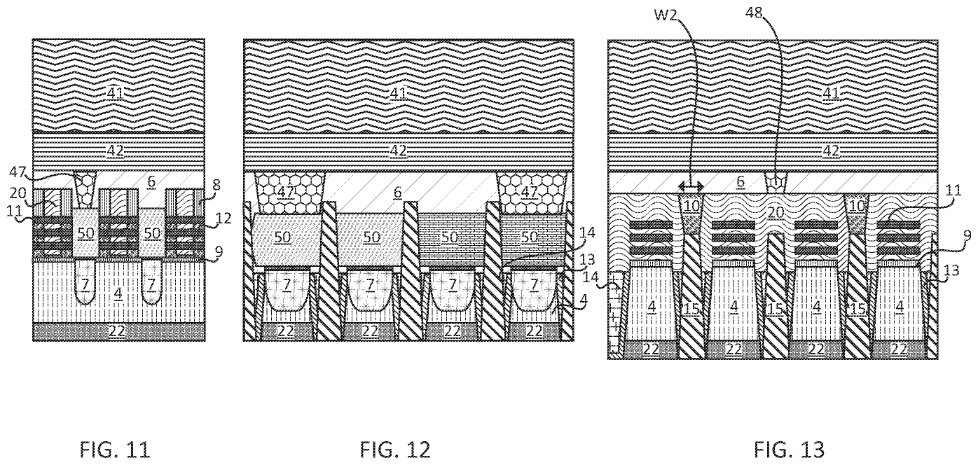

FIGS. 11-13 illustrate one embodiment of a resultant structure following process steps to provide backside source/drain cut structures 45 that are self-aligned, and a back gate cut 15 that is self-aligned to the front gate cut 10. FIGS. 11-13 illustrate an etch process to provide an opening that separates any merged epitaxial semiconductor material for the source/drain regions 50. FIGS. 11-13 also illustrate an etch process to provide an opening the extends to and is aligned with the front gate cut 10. Each of these openings is then filled with dielectric material to provide the back gate cut 15 and the front gate cut 10.

The etch process removes the exposed portions of the shallow trench isolation liner 13 selectively to the dielectric cap 22. In this manner, the dielectric cap 22 may be employed as an etch mask. The openings for the backside source/drain cut structures 45, and a back gate cut 15 are formed through the shallow trench isolation fill 14. Further, because the shallow trench isolation liner 13 is removed from only the base of the isolation region, and the openings are formed through the portion of the shallow trench isolation fill 14 that is exposed by the removed portions of the liner; the openings that are being formed are centrally positioned through the backside of the shallow trench isolation region. Therefore, because the front gate cut 10 is centrally positioned over the shallow trench isolation region, the openings being formed at this stage of the method through the middle of the shallow trench isolation region are aligned to the front gate cut 10, as depicted in FIG. 13. Further, the shallow trench isolation regions are also centrally positioned under the portions of the source and drain epitaxial semiconductor material that potentially merge. Therefore, because the merging portions of the source/drain regions 50 is centrally positioned over the shallow trench isolation region, the openings being formed at this stage of the method are aligned to the merged portions of the epitaxial semiconductor material for the source/drain regions 50, as depicted in FIG. 12.

In some embodiments, the etch process for forming the openings for the backside source/drain cut structure 45 and the back gate cut 15 is a two stage etch. The first stage of the two stage etch may be a self-aligned backside cut that lands over the gate dielectric, e.g., high-k gate dielectric, such as a gate dielectric composed of hafnium oxide, and a backside of the front gate cut 10. The second stage of the two stage etch includes an etch chemistry that etches the material of the source and drain regions 50 more than the material of the gate structure 20. The etch process for forming the openings for the backside source and drain cut structures 45 and the back gate cut 15 is an anisotropic etch, such as reactive ion etching.

Still referring to FIGS. 11-13, the openings for the backside source/drain cut structure 45 and the back gate cut 15 are filled with a dielectric material, such as an oxide, e.g., silicon oxide, or a nitride, e.g., silicon nitride, or an oxynitride, e.g., silicon oxynitride. The deposition method for the fill of the openings for the backside source/drain cut structure 45 and the back gate cut 15 may include chemical vapor deposition, e.g., metal organic chemical vapor deposition and/or plasma enhanced chemical vapor deposition. Following deposition, the dielectric material may be planarized, e.g., by chemical mechanical planarization, stopping on the dielectric cap 22.

By performing the back gate cut 15 from the backside of the device, and contacting the back gate cut 15 to the front gate cut 10 having the shallow depth, the structures and methods of the present disclosure can reduce the width dimension of the front gate cut 10 when compared to the previous processes that do not employ a back gate cut 15. This is advantageous in height scaling for the gate structure 20.

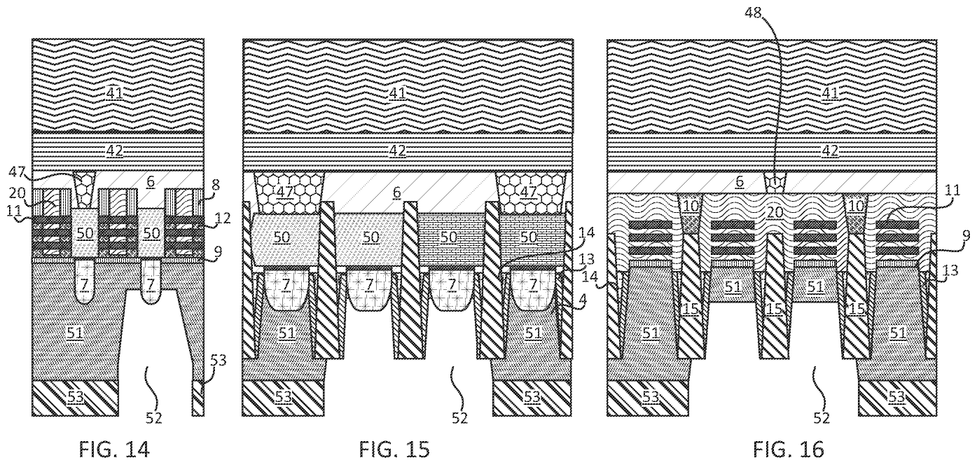

FIGS. 14-16 illustrate a resulting structure following a process sequence that begins with removing the dielectric cap 22, removing the remaining portions of the upper semiconductor layer 4, and forming a backside interlevel dielectric layer 51. The backside interlevel dielectric layer 51 is similar to the upper interlevel dielectric layer 6. Therefore, the above description of the upper interlevel dielectric layer 6 described above is suitable for at least one embodiment of the backside interlevel dielectric layer 51 that is depicted in FIGS. 14-16. Following deposition, the backside interlevel dielectric layer 51 may be planarized. The planarization process may be provided by chemical mechanical planarization.

FIGS. 14-16 also illustrate patterning the backside interlevel dielectric layer 51. Patterning the backside interlevel dielectric layer 51 may include photolithography to provide a photoresist etch mask 53. Following the formation of the photoresist etch mask 53, a selective etch process may be performed by forming openings 52 in backside interlevel dielectric layer 51. The selective etch process is selective to the shallow trench isolation liner 13, as well as the dielectric fill for the backside source/drain cut structure 45. In some embodiments, the backside contact etch is self-aligned due to selectivity between the backside interlevel dielectric layer 51, the shallow trench isolation liner 13 and the backside source/drain cut structures 45.

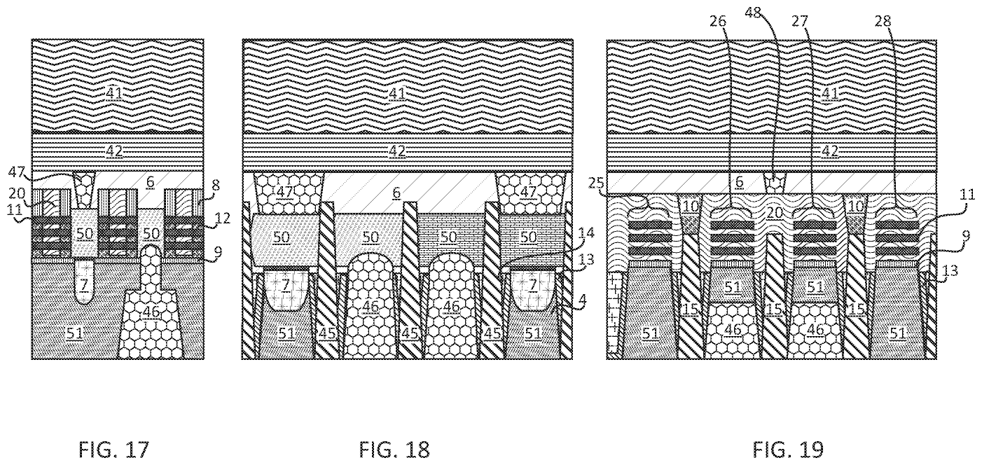

FIGS. 17-19 depict an embodiment that removes the backside contact placeholder 7 and an optional step of gouging the backside of the epitaxial semiconductor material of the source/drain regions 50. In some embodiments, the backside contact placeholder 7 is removed using an etch process, which may be selective to the source/drain regions 50. In a following step, the exposed portion of the source/drain regions 50 that are exposed by removing the backside contact placeholder 7 can then be etched. Gouging the backside surface of the source/drain regions 50 can increase the contact surface area between the backside contact 46 and the source/drain regions 50.

Thereafter, the backside contacts 46 may be formed within the opening created by removing the backside contact placeholder 7. The backside contact 46 may be formed in direct contact with the backside surface of the source/drain regions 50. The backside contacts 46 may be composed of a metal, such as copper, aluminum, platinum, silver, gold, tungsten, and alloys or combinations thereof. The backside contacts 46 may be deposited using plating and/or physical vapor deposition (PVD). Following deposition, a planarization process may be performed, such as chemical mechanical planarization (CMP).

FIGS. 1-4 depict forming the backside power rail 44. In some embodiments, an interlevel backside power dielectric layer 81 is first deposited and then etched to form openings. Thereafter, the openings are then filled with a conductive material, such as a metal, e.g., copper, to provide the backside power rail 44.

Thereafter, a deposition, pattern and fill sequence is repeated to forms lines in backside power distribution network 43. This may be formed using a single damascene method for forming lines and vias. However, dual damascene sequences are also applicable. The sequence of deposition, pattern and etch are repeated as many times as needed to form each level of metal lines and vias.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment. For purposes of the description hereinafter, the terms “upper”, “over”, “overlying”, “lower”, “under”, “underlying”, “right”, “left”, “vertical”, “horizontal”, “top”, “bottom”, and derivatives thereof shall relate to the embodiments of the disclosure, as it is oriented in the drawing figures. The term “positioned on” means that a first element, such as a first structure, is present on a second element, such as a second structure, wherein intervening elements, such as an interface structure, e.g., interface layer, may be present between the first element and the second element. The term “direct contact” means that a first element, such as a first structure, and a second element, such as a second structure, are connected without any intermediary conducting, insulating or semiconductor layers at the interface of the two elements.

Having described preferred embodiments of a methods and structures for dual side gate cut and backside source/drain cut structures for direct backside contacts and backside power distribution networks are disclosed herein, it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

What is claimed is:

1. A semiconductor device comprising:
a row of source/drain regions delineating a frontside and a backside opposite the frontside of the semiconductor device;
a front gate cut from the frontside of the semiconductor device, the front gate cut having a depth that is less than a height of a gate structure for the semiconductor device; and
a back gate cut from the backside of the semiconductor device contacting the front gate cut.

2. The semiconductor device of claim 1, wherein the front gate cut and the back gate cut together divide the gate structure into first gate structure for a first field effect transistor and a second gate structure for a second field effect transistor.

3. The semiconductor device of claim 2, wherein at least one of the first field effect transistor and the second field effect transistor is a nanosheet device.

4. The semiconductor device of claim 1, wherein source regions of the row of source/drain regions are separated from drain regions of the source/drain regions by backside source/drain cut structures.

5. The semiconductor device of claim 1, wherein the back gate cut extends through an isolation region.

6. The semiconductor device of claim 1, wherein at least one source/drain region from the row of source/drain regions is electrically contacted by a backside contact to a power distribution network.

7. The semiconductor device of claim 1, wherein the back gate cut has a height that is less than the height of the gate structure.

8. A semiconductor device comprising:
a row of source/drain regions delineating a frontside and a backside opposite the frontside of the semiconductor device;
a front gate cut from the frontside of the semiconductor device, wherein the front gate cut has a depth that is less than a height of a gate structure for the semiconductor device;
a back gate cut from the backside of the semiconductor device which contacts the front gate cut; and
backside source/drain cut structures.

9. The semiconductor device of claim 8, wherein the backside source/drain cut structures are disposed between source/drain regions of the row of source/drain regions.

10. The semiconductor device of claim 8, wherein the front gate cut and the back gate cut together divide the gate structure into first gate structure for a first field effect transistor and a second gate structure for a second field effect transistor.

11. The semiconductor device of claim 10, wherein at least one of the first field effect transistor and the second field effect transistor is a nanosheet device.

12. The semiconductor device of claim 8, wherein the back gate cut extends through an isolation region.

13. The semiconductor device of claim 8, wherein at least one source/drain region from the row of source/drain regions is electrically contacted by a backside contact to a power distribution network.

14. The semiconductor device of claim 8, wherein the back gate cut has a height that is less than the height of the gate structure.

15. A semiconductor device comprising:
a gate structure in contact with a first stack of nanosheets and a second stack of nanosheets;
a front gate cut having a depth that is less than a height of the gate structure; and
a back gate cut contacting the front gate cut, wherein the front gate cut in combination with the back gate cut together divide the gate structure into a first gate structure and a second gate structure.

16. The semiconductor device of claim 15, wherein the back gate cut has a height that is less than the height of the gate structure.

17. The semiconductor device of claim 15, wherein the back gate cut extends through an isolation region.

18. The semiconductor device of claim 15, further comprising at least one source/drain region that is electrically contacted by a backside contact to a power distribution network.

19. The semiconductor device of claim 15, wherein the first gate structure is for a first field effect transistor and the second gate structure is for a second field effect transistor, wherein a first source/drain region for the first field effect transistor is separated from a second source/drain region for the second field effect transistor by a backside source/drain cut structure.

20. The semiconductor device of claim 15, wherein the gate structure is a gate all around gate structure.
